(19) United States
(12) Patent Application Publication
(10) Pub. No.: US 2005/0098778 A1
(43) Pub. Date: May 12, 2005

(54) Burn-in test adapter and burn-in test apparatus

(75) Inventors: Mitsunori Matsunaga, Tokyo (JP); Tsugumi Matsuishi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/615,243

(22) Filed: Jul. 9, 2003

(30) Foreign Application Priority Data
Jan. 21, 2003 (JP) 2003-012182

(51) Int. Cl. H01L 21/66

(52) U.S. Cl. 257/48

(57) ABSTRACT

An assembly substrate, on which semiconductor chips, each having a terminal receiving a burn-in test waveform, are arranged, is detachably attached to a burn-in test adapter. The burn-in test adapter has wiring for, when an assembly substrate is attached to the burn-in test adapter, making an electrical contact with the terminal of each of the semiconductor chips on the assembly substrate. Moreover, the burn-in test adapter has a burn-in test terminal that is electrically connected to the wiring and that receives the burn-in test waveform.

### BACKGROUND OF THE INVENTION

1) Field of the Invention

The present invention relates to a test apparatus that tests a semiconductor integrated device for initial defect. More particularly, this invention relates to a burn-in test adapter and a burn-in test apparatus.

2) Description of the Related Art

Generally, it is examined before shipment whether the semiconductor chips are faulty before their shipment (hereafter, “initial defect”). The initial defect may occur in the semiconductor chips in the manufacturing process. Only the good semiconductor chips, which pass this examination, are shipped. The inspection of the initial defects of the semiconductor chips and malfunctions at the manufacturing steps of the semiconductor chips is conducted by a test called “burn-in test”. In this burn-in test, a semiconductor chip is put in a high temperature environment, e.g., 125° C. (degree centigrade), in which a voltage or a signal is applied to the semiconductor chip.

A wafer, on which semiconductor chips are formed, is cut into pieces, then the semiconductor chips are assembled and finished as semiconductor integrated devices. The conventional burn-in test is conducted on these semiconductor devices. When performing the burn-in test, the semiconductor integrated devices are attached to a burn-in board, on which burn-in test wirings are provided, and a burn-in test input waveform is input through the input terminals of the respective semiconductor integrated devices.

The conventional burn-in test has, however, the following disadvantage. Since the conventional burn-in test is conducted after the semiconductor chips are packaged into the semiconductor integrated devices, packaging steps and materials used at the packaging steps for the semiconductor integrated devices that are determined to be bad are wasted.

To solve this disadvantage, Japanese Patent Application Laid-Open No. 4-312943 (see page 3) discloses performing the burn-in test before the semiconductor chips are assembled into semiconductor integrated devices. According to this publication, a burn-in test wiring and a burn-in test terminal are formed first on a burn-in test substrate (hereinafter, “sub-substrate”). A plurality of semiconductor chips thus cut off according to the chips are mounted on the sub-substrate, the burn-in test terminal is electrically connected to the pad of each semiconductor chip, thus conducting the burn-in test. After it is determined by such a burn-in test whether the semiconductor chips are good, the sub-substrate on which the semiconductor chips are mounted is cut off together with each of the semiconductor chips. Only the semiconductor chips on the sub-substrates that are determined as good chips are packaged, together with the sub-substrates, on a main substrate, and shipped as semiconductor integrated devices.

According to the technology disclosed in the above-mentioned publication, the burn-in test is executed while mounting the semiconductor chips on the sub-substrate, and the sub-substrate is cut off together with each of the chips and mounted on the main substrate. Therefore, it is unnecessary to conduct a test to decide whether the product is good or bad (hereinafter, “GOOD/BAD test”) to the respective semiconductor chips after the chips are mounted on the main substrate, thus improving efficiency for the semiconductor chip GOOD/BAD test operation.

However, since the sub-substrates are cut into pieces after the burn-in test, the sub-substrates can not be recycled. Therefore, it is necessary to form a burn-in test wiring and a burn-in test terminal for each semiconductor chip to be tested on the sub-substrate. As a result, the cost of the sub-substrate for mounting thereon semiconductor chips is disadvantageously pushed up.

When the sub-substrate is cut into pieces, the wiring on the sub-substrate is also cut. As a result, the service life of a substrate cutting device such as a rotational blade is disadvantageously shortened, the cost of the burn-in test is disadvantageously pushed up, and cost for obtaining the semiconductor chips is disadvantageously pushed up.

The burn-in test is conducted while a plurality of semiconductor chips are mounted on one sub-substrate. To increase the number of semiconductor chips to be measured at one time, there is disadvantageously no choice but increasing the size of the sub-substrate.

### SUMMARY OF THE INVENTION

It is an object of the present invention to solve at least the problems in the conventional technology.

The burn-in test adapter according to one aspect of the present invention includes a wiring in such a manner that, when an assembly substrate is attached to the burn-in test adapter, the wiring makes an electrical contact with the terminal of each of semiconductor chips on the assembly substrate; and a burn-in test terminal electrically connected to the wiring and receiving a burn-in test waveform.

The burn-in test apparatus according to one aspect of the present invention includes the burn-in test adapter, which is rectangular and the burn-in test terminal is arranged on one of the four sides, a socket that holds the burn-in test adapter at the side on which the burn-in test terminal is arranged and that is electrically connected to the burn-in test terminal; and a burn-in board that holds the socket and that includes a wiring that is electrically connected to the socket, wherein the wiring receives the burn-in test waveform.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 illustrates the configuration of a burn-in test adapter according to the present invention;

FIG. 2 illustrates the configuration of a burn-in test adapter according to a first embodiment according to the present invention;

FIG. 3 illustrates the configuration of a burn-in test adapter according to a second embodiment according to the present invention; and

FIG. 4 illustrates the configuration of a burn-in test apparatus according to a third embodiment according to the present invention.

### DETAILED DESCRIPTION

Exemplary embodiments of a burn-in test adapter and a burn-in test apparatus according to the present invention are explained below in detail with reference to the accompanying drawings. It should be noted that these embodiments are not intended to limit the present invention.

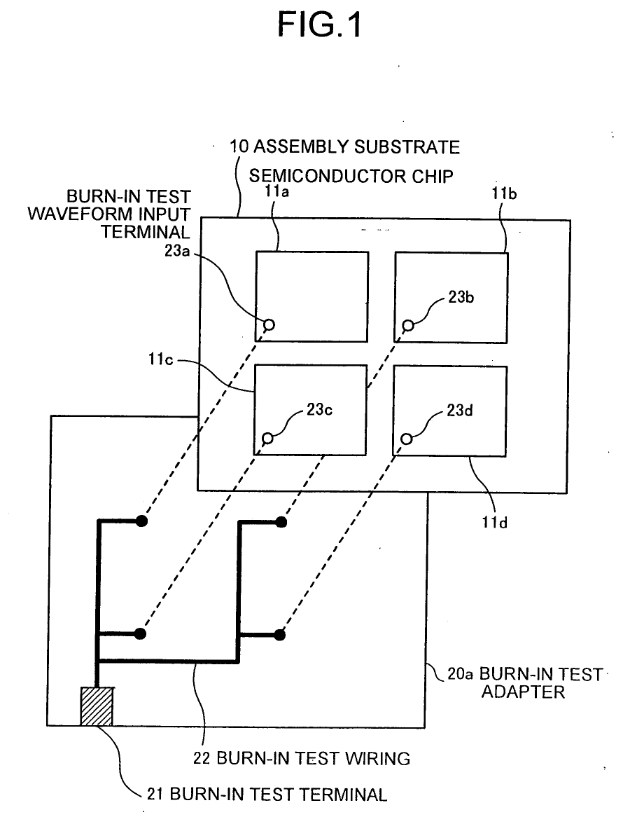

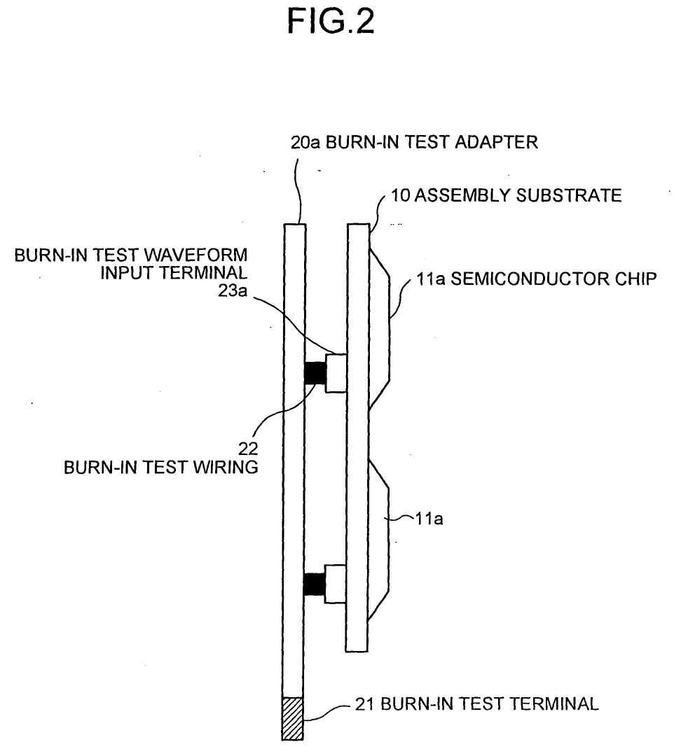

A first embodiment of the present invention will be explained with reference to FIGS. 1 and 2. FIG. 1 is a top view of a schematic configuration of the burn-in test adapter according to the present invention. FIG. 2 is a side view of the schematic configuration of a burn-in test adapter according to a first embodiment of the present invention.

A plurality of semiconductor chips 11a, 11b, 11c, 11d are mounted on and electrically connected to one surface (hereinafter, “front surface”) of an assembly substrate 10. The front surface is a surface of the assembly substrate 10 that is a surface (hereinafter, “rear surface”) that is opposite to a surface that comes in contact with a burn-in test adapter 20a. Burn-in test waveform input terminals 23a, 23b, 23c, 23d are arranged on the rear surface of the assembly substrate 10. The burn-in test waveform input terminals 23a, 23b, 23c, 23d are electrically connected to the semiconductor chips 11a, 11b, 11c, 11d, respectively, through wirings. The semiconductor chips 11a, 11b, 11c, 11d are collectively referred to as semiconductor chips 11, and the burn-in test waveform input terminals 23a, 23b, 23c, 23d are collectively referred to as burn-in test waveform input terminals 23.

The burn-in test adapter 20a is a device that examines the semiconductor chips 11. The assembly substrate 10 is detachable from the burn-in test adapter 20a. A burn-in test terminal 21 and a burn-in test wiring 22 are arranged on one surface (hereinafter, “front surface”) of the burn-in test adapter 20a. The front surface of the burn-in test adapter 20a is a surface that comes in contact with the assembly substrate 10.

The burn-in test terminal 21 electrically connects a not shown burn-in test input waveform generator to the burn-in test adapter 20a.

The burn-in test wiring 22 is provided on the burn-in test adapter 20a so as to propagate an input waveform from the burn-in test input waveform generator to the burn-in test waveform input terminals 23 of the assembly substrate 10 when the assembly substrate 10 is attached to this burn-in test adapter 20a. The burn-in test wiring 22 electrically connects the burn-in test terminal 21 to the burn-in test waveform input terminals 23. The burn-in test wiring 22 extended from the burn-in test terminal is constituted to be branched halfway along the wiring and the branched wirings are connected to the burn-in test waveform input terminals 23, individually.

One burn-in test wiring 22 is provided to be connected to the burn-in test waveform input terminals 23 since the burn-in test waveform input terminals 23, each of which is coupled to one pad on each semiconductor chip 11, are connected to the burn-in test wiring 22.

The explanation given above assumes that each semiconductor chip 11 provided with one pad. However, each semiconductor chip 11 may be provided with a plurality of pads and these pads may be electrically connected to the burn-in test waveform input terminals 23. When each semiconductor chip 11 is provided with a plurality of pads, the number of burn-in test wirings 22 is equal to that of the pads, and each burn-in test waveform input terminal 23 is electrically connected to a plurality of burn-in test wirings 22. The burn-in test wirings 22 are extended as a bundle from the burn-in test terminal 21 to the burn-in test waveform input terminals 23 so as not to contact one another. Just before being input to the burn-in test waveform input terminals 23, the wiring 22 is branched into a plurality of wirings and the branched wirings are electrically connected to the burn-in test waveform input terminals 23, respectively.

The semiconductor chips 11 and the burn-in test waveform input terminals 23 are arranged on the assembly substrate 10 so as to be electrically connected on a one-by-one correspondence such as the semiconductor chip 11a to the burn-in test waveform input terminal 23a, the semiconductor chip 11b to the burn-in test waveform input terminal 23b, the semiconductor chip 11c to the burn-in test waveform input terminal 23c and so on.

Wirings are provided on the rear surface and inside of the assembly substrate 10 in order to connect the burn-in test waveform input terminals 23 to the semiconductor chips 11, respectively. By connecting the burn-in test adapter 20a to the assembly substrate 10, the burn-in test terminal 21, the burn-in test wiring 22, the burn-in test waveform input terminals 23, the assembly substrate 10, and the semiconductor chips 11 are electrically connected.

By thus providing the burn-in test adapter 20a, it is possible to conduct a burn-in test to the semiconductor chips 11 without providing the burn-in test wiring or the burn-in test terminal on the assembly substrate 10.

A burn-in test method conducted while using the burn-in test adapter in the first embodiment will next be explained. A wafer from which a plurality of semiconductor chips 11 are formed is cut into pieces according to the semiconductor chips 11, and the semiconductor chips 11 are mounted on the assembly substrate 10 so as to be electrically connected thereto. The assembly substrate 10 on which the semiconductor chips 11 are mounted is electrically connected to the burn-in test adapter 20a.

The burn-in test adapter 20a is then connected to the burn-in test input waveform generator. The semiconductor chips 11 are put in a high temperature environment, e.g., 125° C., and a burn-in test input waveform is generated from the burn-in test input waveform generator. The burn-in test input waveform generated from the burn-in test input waveform generator is input to the semiconductor chips 11 through the burn-in test terminal 21, the burn-in test wiring 22, and the respective burn-in test waveform input terminals 23. The semiconductor chips 11 into which the burn-in test input waveform is thus input are kept in this state for a predetermined time. Thereafter, the assembly substrate 10 is detached from the burn-in test adapter 20a. Since this burn-in adapter 20a is not formed integrally with the assembly substrate 10, it can be recycled without being cut off and used for the next burn-in test.

The assembly substrate 10 is then cut into pieces so as to be separated according to the respective semiconductor chips 11. Since the burn-in test wiring 22 is not provided on the assembly substrate 10, it is unnecessary to cut off a metal wiring during the cutoff of the assembly substrate 10. Finally, the assembly substrate 10 is cut into pieces so as to be separated according to the respective chips, and it is determined whether each chip is good in a later test to detect an initial defect thereof. Only the substrates 10 determined to be good are moved to the next step and packaged.

As explained above, according to the first embodiment, the burn-in test adapter 20a is constituted to include the burn-in test wiring 22 and the burn-in test terminal 21. Therefore, it is not necessary to form the burn-in test wiring and the burn-in test terminal on the assembly substrate 10. As a result, cost reduction becomes possible.

Since the burn-in test adapter 20a can be recyclable, it is possible to reduce the cost of the burn-in test. Further, since it is unnecessary to cut the burn-in test wiring 22 on the burn-in test adapter into pieces, the service life of the substrate cutting device such as a rotational blade or the like to be used for cutting is not shortened.

Consequently, by employing the burn-in test adapter 20a, it is possible to obtain the burn-in test apparatus that can conduct a test at low cost.

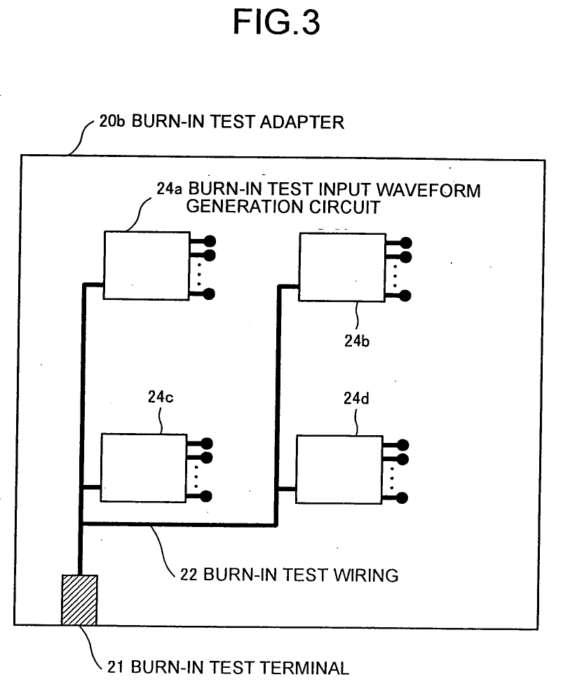

A second embodiment of the present invention is explained below with reference to FIG. 3. The second embodiment is characterized by providing a circuit, which increases the number of input signals that can be applied during a burn-in test, on a burn-in test adapter.

FIG. 3 is a schematic diagram of the configuration of a burn-in test adapter 20b according to the second embodiment. Among the elements shown in FIG. 3, those that have same or similar configuration or same of similar function as those elements shown in FIG. 1 have been denoted by the same reference symbols and their explanation is omitted.

The burn-in test adapter 20b consists of a plurality of burn-in test input waveform generation circuits 24a, 24b, 24c, 24c, the burn-in test wiring 22, and the burn-in test terminal 21. Each of the burn-in test input waveform generation circuits 24 generates, for example, a plurality of burn-in test input waveforms from one burn-in test input waveform. The burn-in test input waveform generation circuits 24a, 24b, 24c, 24c are collectively referred to as burn-in test input waveform generation circuits 24.

The burn-in test input waveform generation circuits 24 are arranged on the burn-in test adapter 20b at positions at which the circuits 24 are electrically connected to the burn-in test waveform input terminals 23 near thereof, respectively when the assembly substrate 10 is attached to the burn-in test adapter 20b. The circuits 24 as many as the semiconductor chips 11 that can be arranged on the burn-in test adapter 20b are arranged on the burn-in test adapter 20b. By so arranging, the burn-in test input waveform generation circuits 24 can generate burn-in test input waveforms to the semiconductor chips, respectively.

It is normally known that if a plurality of pads are used for the burn-in tests conducted to the semiconductor chips 11, it is necessary to provide as many wirings as the pads are necessary and to input appropriate input waveforms to the respective wirings. By way of example, in the second embodiment, one burn-in test wiring 22 is branched into a plurality of wirings according to the burn-in test input waveform generation circuits 24.

It is assumed, for example, that one burn-in test input waveform is fed to the burn-in test input waveform generation circuits 24 through the burn-in test terminal 21 and the burn-in test wiring 22. Each burn-in test input waveform generation circuit 24 can branch this single input waveform to a plurality of wirings, output the branched waveforms to a plurality of terminals in the burn-in test input terminals 23, and input them to the respective semiconductor chips 11. It is also possible to output a plurality of types of waveforms to the wirings after they are branched.

As can be seen, one burn-in test wiring 22, for example, is branched into a plurality of wirings according to the burn-in test respective input waveform generation circuits 24, and then the wirings are electrically connected to a plurality of pads, which the semiconductor chips 11 include, through the burn-in test waveform input terminals 23, respectively. This can simplify the wiring structure of the burn-in test wiring 22, as compared with the configuration in which a plurality of burn-in test wirings 22 are extended from the burn-in test terminal 21 and in which the wirings are electrically connected to the plurality of pads, which the semiconductor chips 11 include. In addition, if the burn-in test wiring 22 is simplified, it is possible to facilitate decreasing the number of the burn-in test terminals 21.

A burn-in test method conducted by using the burn-in test adapter in the second embodiment will be explained. A burn-in test input waveform from the burn-in test input waveform generator, not shown, is fed to the burn-in test wiring 22 through the burn-in test terminal 21. This input waveform is fed to the burn-in test input waveform generation circuits 24 by this burn-in test wiring 22. The burn-in test input waveform generation circuits 24 branch the input waveform into pieces according a desired number of wirings, convert the branched input waveforms into a plurality of types of waveforms, and input them into the respective semiconductor chips 11.

As can be seen, according to the second embodiment, by providing the burn-in test input waveform generation circuits 24, it is possible to decrease the number of wirings provided in the burn-in test adapter 20b and the number of the burn-in test wirings 21, thereby simplifying the structure of the burn-in test adapter 20b and facilitating the creation of the adapter 20b.

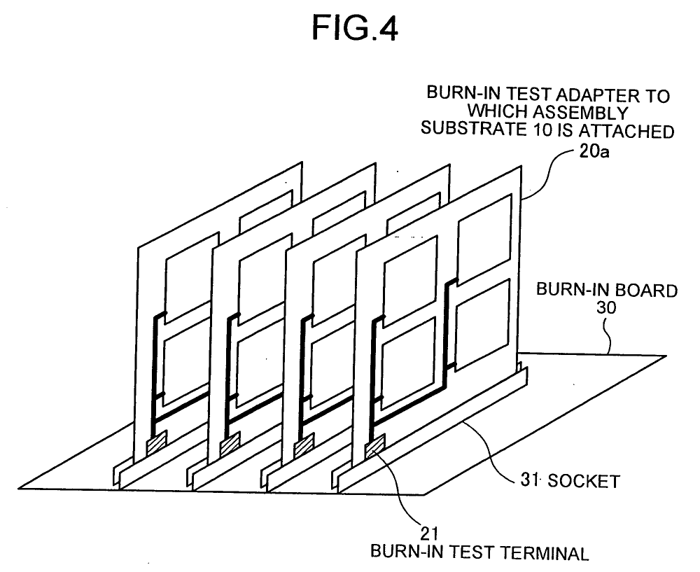

A third embodiment of the present invention is explained below with reference to FIG. 4. The third embodiment is such that a burn-in board that enables the execution of a burn-in test at one time, even if there are a plurality of burn-in test adapters, is further provided.

FIG. 4 is a schematic diagram of the configuration of the burn-in test apparatus according to the present invention. Among the constituent elements of the burn-in test apparatus shown in FIG. 4, those equal in function to the burn-in test adapter 20a and the like in the first embodiment shown in FIGS. 1 and 2 are denoted by the same reference symbols, respectively, and will not be repeatedly explained herein.

The burn-in test apparatus in the third embodiment consists of the burn-in test adapter 20a to which the assembly substrate 10 can be attached, a the burn-in board 30.

The burn-in test adapter 20a is equal in configuration to that in the first embodiment. In FIG. 4, a state in which the assembly substrate 10 is attached to the burn-in test adapter 20a is shown. One to a plurality of such assembly substrates 10 are prepared. Each assembly substrate 10 and each burn-in test adapter 20a are fixed onto the burn-in board 30 by fixing units such as clippers using springs, for example, at positions at which the burn-in test wiring 22 is electrically connected to the burn-in test waveform input terminals 23.

The burn-in test terminal 21 on the burn-in test adapter 20a is arranged on a part of the outermost periphery of the burn-in test adapter 20a as shown in FIG. 1 so as to facilitate the connection of the burn-in test adapter 20a to the burn-in board 30. It is also possible to arrange a plurality of burn-in test terminals 21 on the burn-in test adapter 20a.

The burn-in board 30 is a board that feeds an input waveform from the burn-in test waveform generator, not shown, to the burn-in test adapter 20a. A socket 31 on the burn-in board 30 electrically connects the burn-in test terminal 21 in the burn-in test adapter 20a to the burn-in board 30, and fixes the burn-in test adapter 20a to the burn-in board 30. A plurality of sockets 31 may be provided. In the latter case, a plurality of burn-in test adapters 20a can be attached onto the burn-in board 30. The electrical connection of the burn-in adapter 20a to the burn-in board 30 is established by inserting the burn-in test terminal 21 in the burn-in test adapter 20a into the socket 31 on the burn-in board 30. By so inserting, the burn-in test terminal 21 is electrically connected to the socket 31.

One to a plurality of burn-in test adapters 20a to which the assembly substrates 10 are attached, respectively, are provided. The burn-in test adapters 20a are connected to the burn-in board 30 three-dimensionally while the burn-in test adapters 20a are built vertically to the upper surface of the burn-in board 30.

Thus, the attachment of the burn-in test adapters 20a onto the burn-in board 30 can be made three-dimensionally using the burn-in test terminals 21 provided on the outermost peripheries of the burn-in test adapters 20a connected to the assembly substrates, respectively.

A burn-in test method conducted by using the burn-in test apparatus in the third embodiment will next be explained. The semiconductor chips 11 are mounted on the assembly substrate 10 so as to be electrically connected thereto. The assembly substrate 10 on which the semiconductor chips 11 are mounted is electrically connected to the burn-in test adapter 20a.

In order to electrically connect the burn-in test adapter 20a, on which the semiconductor chips 11 are mounted, to the burn-in board 30, the burn-in test terminal 21 of the burn-in test adapter 20a is attached to the socket 31 on the burn-in board 30.

Thereafter, the burn-in board 30 is connected to the burn-in test input waveform generator, not shown, the semiconductor chips 11 are put in a high temperature environment, e.g., 125° C., and a burn-in test waveform is generated from the burn-in test input waveform generator. The burn-in test input waveform from the burn-in test input waveform generator is passed through wirings arranged on the burn-in board 30, and input to the semiconductor chips 11 through the socket 31, the burn-in test terminal 21, the burn-in test wiring 22, and the respective burn-in test input terminals 23.

The semiconductor chips 11 to which the burn-in test input waveform is thus input are kept in this state for a predetermined time, and then the assembly substrate 10 connected to the semiconductor chips 11 is detached from the burn-in test adapter 20a. Finally, the assembly substrate 10 is cut into pieces so as to be separated according to the chips, the chips are determined whether they are good in a later test, and only the chips that are determined good are moved to the next step and packaged.

In the third embodiment, the use of the burn-in test adapter 20a in the first embodiment has been explained. Alternatively, the burn-in test adapter 20b in the second embodiment may be used.

As can be seen, according to the third embodiment, the burn-in test terminal 21 is provided on the outermost periphery of the burn-in test adapter 20a, and the burn-in board 30 is provided in the burn-in test apparatus. Therefore, the burn-in test adapter 20a can be attached three-dimensionally, making it possible to increase the number of burn-in test measurement target chips to be tested at one time in a small space.

Since it is unnecessary to detach the semiconductor chips 11 from the assembly substrate 10 after the burn-in test is executed, it is possible to decrease the number of operation steps.

Further, since the semiconductor chips 11 can be subjected to the burn-in test before being packaged on the semiconductor integrated devices, it is possible to discriminate good semiconductor chips 11 from bad semiconductor chips 11 before packaging. It is thereby possible to package only the good chips without the need to package the bad chips, thus reducing the manufacturing cost of the semiconductor integrated devices.

As explained so far, according to one aspect of the present invention, it is unnecessary to form the burn-in test wiring and the burn-in test terminal on the assembly substrate, and to cut off the burn-in test wiring on the burn-in test adapter. Therefore, it is possible to prevent the service life of the substrate cutting device used to cut off the assembly substrate from being shortened. Besides, since it is possible to recycle the burn-in test adapter, it is advantageously possible to obtain the burn-in test apparatus that can conduct the test at low cost.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

1. A burn-in test adapter to which an assembly substrate, on which a plurality of semiconductor chips, each having a terminal receiving a burn-in test waveform, are arranged, is detachably attached, comprising:
wiring for, when the assembly substrate is attached to the burn-in test adapter, making electrical contact with the terminals of each of the semiconductor chips on the assembly substrate; and
a burn-in test terminal electrically connected to the wiring and receiving the burn-in test waveform.

2. The burn-in test adapter according to claim 1, further comprising a burn-in test waveform generation circuit that increases the number of the burn-in test waveforms, and located on the wiring at positions that correspond to positions of the individual semiconductor chips when the assembly substrate is attached to the burn-in test adapter.

3. The burn-in test adapter according to claim 1, wherein the burn-in test adapter is rectangular and has four sides, and the burn-in test terminal is located on one of the four sides of the burn-in test adapter.

4. A burn-in test apparatus comprising:
a burn-in test adapter to which an assembly substrate, on which a plurality of semiconductor chips, each having a terminal receiving a burn-in test waveform, are arranged, is detachably attached, the burn-in test adapter including:
first wiring for, when the assembly substrate is attached to the burn-in test adapter, making an electrical contact with the terminals of each of the semiconductor chips on the assembly substrate; and
a burn-in test terminal electrically connected to the first wiring and receiving the burn-in test waveform, wherein the burn-in test adapter is rectangular and has four sides, and the burn-in test terminal is located on one of the four sides of the burn-in test adapter;
a socket that holds the burn-in test adapter at the side on which the burn-in test terminal is located and that is electrically connected to the burn-in test terminal; and
a burn-in board that holds the socket and that includes second wiring that is electrically connected to the socket, wherein the second wiring receives the burn-in test waveform.

5. The burn-in test apparatus according to claim 4, including a plurality of the sockets.

6. A burn-in test adapter to which an assembly substrate, on which a plurality of semiconductor chips, each having a chip-side terminal for receiving a burn-in test waveform, are arranged, is detachably attached, comprising:
an adapter-side terminal corresponding to each chip-side terminal, wherein the adapter-side terminal is located so that, when the assembly substrate is attached to the burn-in test adapter, the adapter-side terminal makes electrical contact with the corresponding chip-side terminal;
a signal receiving terminal that receives the burn-in test waveform; and
wiring that electrically connects the adapter-side terminal to the signal receiving terminal.
